(19) United States
(12) Patent Application Publication
(10) Pub. No.: US 2015/0268555 A1
(43) Pub. Date: Sep. 24, 2015

(54) POSITIVE RESIST COMPOSITION AND PATTERNING PROCESS

(71) Applicant: SHIN-ETSU CHEMICAL CO., LTD., Tokyo (JP)

(72) Inventors: Kenji FUNATSU, Jyoetsu (JP); Akihiro SEKI, Jyoetsu (JP); Takeshi SASAMI, Jyoetsu (JP)

(21) Appl. No.: 14/621,872

(22) Filed: Feb. 13, 2015

(30) Foreign Application Priority Data
Mar. 19, 2014 (JP) 2014-56124

(51) Int. Cl. G03F 7/039; G03F 7/16; G03F 7/20

(52) U.S. Cl. CPC G03F 7/039; G03F 7/2041; G03F 7/2002; G03F 7/16

(57) ABSTRACT

The present invention provides a positive resist composition comprising: (A) a resin having repeating units represented by the following general formula (1) and the following general formula (2) as repeating units containing an acid-labile group, and an alkali solubility of which being increased by an acid, (B) a photoacid generator, (C) a compound represented by the following general formula (3), and (D) a solvent. There can be provided a positive resist composition which can provide a pattern excellent in resolution, in particular excellent in depth of focus (DOF) characteristics, and having good line width roughness (LWR).

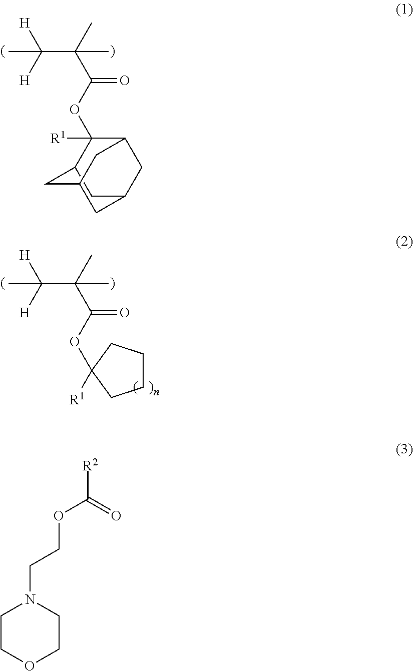

### BACKGROUND OF THE INVENTION

1. Field of the Invention

The present invention relates to a positive resist composition and a patterning process using the same.

2. Description of the Related Art

In the ArF liquid immersion lithography, it has been proposed to impregnate water between a projection lens and a wafer. A refractive index of water at 193 nm is 1.44, so that patterning can be carried out even when a lens having a numerical aperture (NA) of 1.0 or more is used, and the NA can be theoretically raised to 1.35. Resolution is improved in proportion to the improvement in NA, and it has been suggested the possibility that a combination of a lens having NA of 1.2 or more and a super-resolution technology can be used in 45 nm node (Non-Patent Document 1).

In the liquid immersion lithography, various problems due to the presence of water on a resist film have been pointed out. For example, there are problems that a pattern shape has been changed or a projection lens of an exposure apparatus is contaminated, etc., by the reason that a photoacid generator in the resist material, an acid generated by photo irradiation, and an amine compound added to the resist film as a quencher are eluted into water contacting therewith (leaching).

To prevent these problems, there is a method in which a top coat is formed on a resist film to suppress leaching. While leaching can be suppressed by the top coat, however, the problem of deterioration in the pattern shape or resolution has emerged. With regard to the pattern shape, there is a problem that top loss in which the head thereof becomes round is occurred.

Also, in accordance with further increase in the demand for higher resolution, improvement in various lithographic characteristics has been required. Among them, improvement in depth of focus (DOE′) characteristics and line width roughness (LWR) has been required to improve process margin, etc., at the time of forming a pattern.

### PRIOR ART DOCUMENTS

### Non-Patent Documents

Non-Patent Document 1: Proc. SPIE Vol. 5040 p.724

### SUMMARY OF THE INVENTION

The present invention was made in view of the circumstances, and an object thereof is to provide a positive resist composition excellent in resolution, in particular excellent in depth of focus (DOF) characteristics, and which can provide a pattern with good line width roughness (LWR).

It is also an object of the invention to provide a patterning process by liquid immersion lithography using the positive resist composition of the present invention.

To solve the problems, the present invention provides a positive resist composition, comprising:

(A) a resin having repeating units represented by the following general formula (1) and the following general formula (2) as repeating units containing an acid-labile group, and an alkali solubility of which being increased by an acid;

(B) a photoacid generator;

(C) a compound represented by the following general formula (3); and

(D) a solvent,

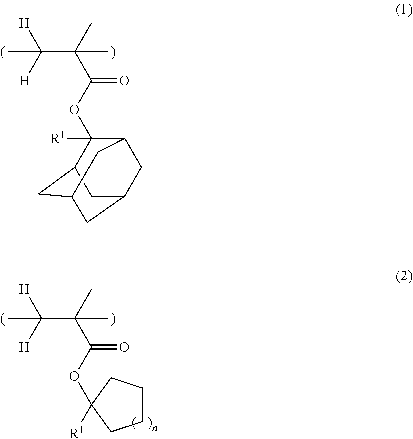

wherein each R¹ independently represents a linear or branched alkyl group having 1 to 10 carbon atoms; and “n” represents an integer of 1 to 3,

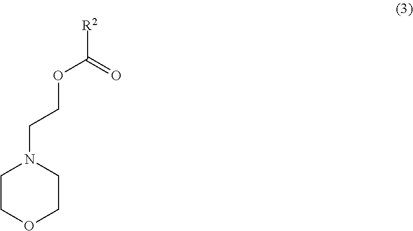

wherein R² represents a linear or branched alkyl group having 10 to 20 carbon atoms which may contain an ether bond(s) and an ester bond(s).

Such a positive resist composition of the present invention is excellent in resolution, and in particular, depth of focus (DOF) characteristics of removing (trench pattern) performance and remaining (isolated pattern) performance are improved. Also, a resist film which can provide a pattern with good LWR can be formed.

Also, at this time, the resin of the Component (A) preferably further contains either or both of a repeating unit(s) represented by the following structural formula (4) and the following structural formula (5).

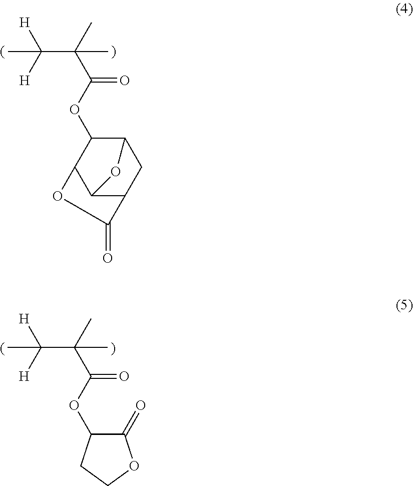

Thus, when the resin of the Component (A) of the present invention further contains a repeating unit(s) of the general formula (4) and/or the general formula (5) each having a lactone ring, the resist film can be excellent in adhesiveness, and a resist pattern having a further preferred shape can be obtained.

Also, at this time, a content of the Component (C) is preferably 0.5 to 10 parts by mass relative to 100 parts by mass of the resin of the Component (A).

When the content of the Component (C) is as mentioned above, the effects of the present invention can be shown sufficiently.

Further, the present invention provides a patterning process, comprising:

forming a photoresist film by coating the above-mentioned positive resist composition on a substrate and subjecting to heat treatment;

forming a top coat on the photoresist film;

subjecting to liquid immersion exposure with a high energy beam having a wavelength of 180 to 250 nm through water; and

developing using an alkali developer.

Thus, when the patterning process of the present invention using the above-mentioned positive resist composition of the present invention is employed, deterioration of the pattern shape or resolution which is likely occurred when liquid immersion exposure is carried out by forming the conventional top coat can be suppressed. Specifically, a pattern shape having high rectangularity can be obtained, and excellent depth of focus (DOF) characteristics, specifically excellent DOF characteristics of a trench pattern and an isolated pattern can be obtained.

As mentioned above, the positive resist composition of the present invention has excellent resolution, in particular good depth of focus (DOF) characteristics in both of the isolated pattern and the trench pattern. In the present invention, an effect that a resist pattern with good LWR is formed can be also obtained. In particular, such a positive resist composition of the present invention is extremely useful in the liquid immersion lithography in which a top coat is formed and exposure is carried out through water.

In addition, when the patterning process of the present invention using such a positive resist composition of the present invention is employed, deterioration of the pattern shape or resolution which is likely occurred when liquid immersion exposure is carried out by forming the conventional top coat can be suppressed. Specifically, a pattern shape having high rectangularity can be obtained, and excellent depth of focus (DOE) characteristics, specifically excellent DOF characteristics of a trench pattern and an isolated pattern can be obtained.

### DETAILED DESCRIPTION OF THE PREFERRED EMBODIMENTS

As mentioned above, it has been required to develop a positive resist composition, for example, which does not generate the problem of top loss, etc., and can suppress deterioration of the pattern shape or resolution, in particular, depth of focus (DOE) characteristics, when a top coat is formed.

The present inventors have earnestly studied to accomplish the problems, and as a result, they have found out that a positive resist composition containing (A) a resin having a repeating unit (the repeating unit represented by the general formula (1) mentioned later) in which a carboxylic acid which is a solubilizable group is protected by an acid-labile group having an adamantane ring, and a repeating unit (the repeating unit represented by the general formula (2) mentioned later) in which a carboxylic acid which is a solubilizable group is protected by an acid-labile group having a specific monocyclic structure; (C) a compound represented by the general formula (3) mentioned below; (B) a photoacid generator; and (D) a solvent, is excellent in resolution and rectangularity of the pattern shape, so that it is extremely useful as a resist material for a precise fine processing, whereby they have accomplished the present invention.

In particular, they have found out that when the positive resist composition of the present invention is employed, good depth of focus (DOE) characteristics in both of an isolated pattern and a trench pattern can be obtained. Incidentally, “DOF” means that a range of the depth of focus which can form a resist pattern with a dimension in which a deviation to the target dimension is within a predetermined range when exposure is carried out by shifting the focus up and down with the same exposure dose, i.e., a range in which a resist pattern faithful to the mask pattern can be obtained, and DOE is preferably as large as possible.

The present invention is a positive resist composition, comprising:

(A) a resin having repeating units represented by the following general formula (1) and the following general formula (2) as repeating units containing an acid-labile group, and an alkali solubility of which being increased by an acid;

(B) a photoacid generator;

(C) a compound represented by the following general formula (3); and

(D) a solvent,

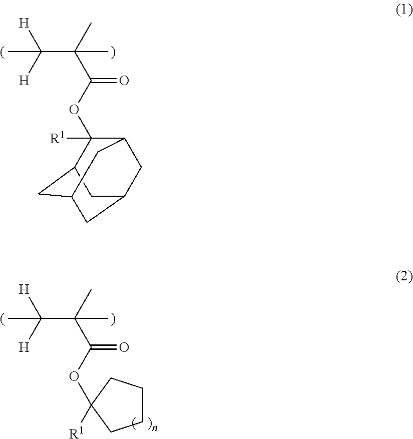

wherein each R¹ independently represents a linear or branched alkyl group having 1 to 10 carbon atoms; and “n” represents an integer of 1 to 3,

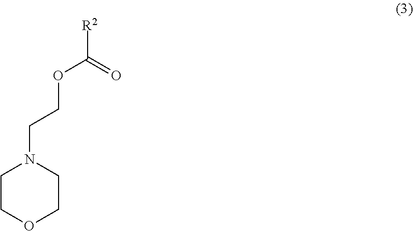

wherein R² represents a linear or branched alkyl group having 10 to 20 carbon atoms which may contain an ether bond(s) and an ester bond(s).

In the following, the present invention is explained in detail, but the present invention is not limited by these.

### <Component (A)>

The positive resist composition of the present invention contains, as a base resin, (A) a resin having repeating units represented by the following general formula (1) and the following general formula (2), and an alkali solubility of the resin is increased by an acid,

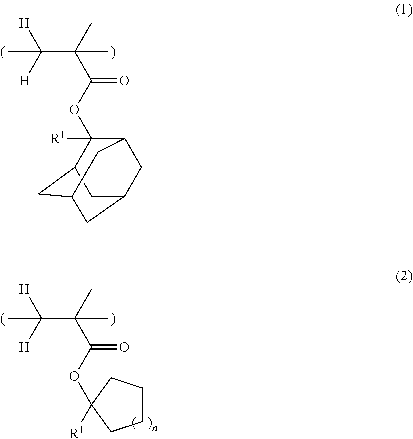

wherein each R¹ independently represents a linear or branched alkyl group having 1 to 10 carbon atoms; and “n” represents an integer of 1 to 3.

The repeating unit represented by the general formula (1) is a repeating unit containing an acid-labile group having an adamantane ring, and a carboxylic acid therein which is a solubilizable group is protected by the acid-labile group. By introducing the repeating unit as a constitutional element of the resin in which an alkali solubility thereof is increased by an acid of the Component (A), high resolution can be obtained.

The repeating unit represented by the general formula (2) is a repeating unit containing an acid-labile group having a specific monocyclic structure, and a carboxylic acid therein which is a solubilizable group is protected by the acid-labile group. By introducing such a monocyclic structural unit as a constitutional element of the resin in which an alkali solubility thereof is increased by an acid of the Component (A), the resulting material becomes a positive resist composition in which fat-solubility can be lowered, dissolution contrast of the resist can be heightened; and in combination with the Component (C) mentioned later, a pattern excellent in resolution, in particular excellent in depth of focus (DOF) characteristics, and having good LWR can be provided.

In the general formulae (1) and (2), each R¹ independently represents a linear or branched alkyl group having 1 to 10 carbon atoms, preferably 1 to 4 carbon atoms.

“n” represents an integer of 1 to 3, preferably 1 or 2.

The repeating unit represented by the general formula (1) is not particularly limited, and the repeating units shown below are particularly preferred.

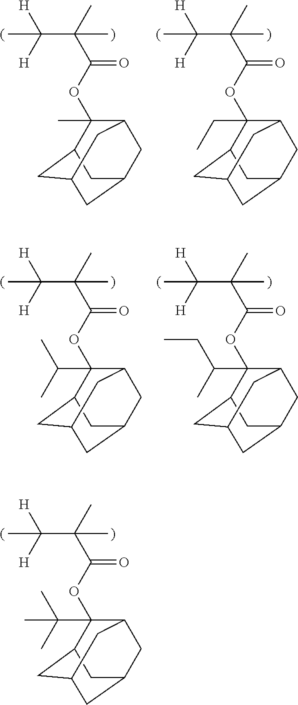

The repeating unit represented by the general formula (2) is not particularly limited, and the repeating units shown below are particularly preferred.

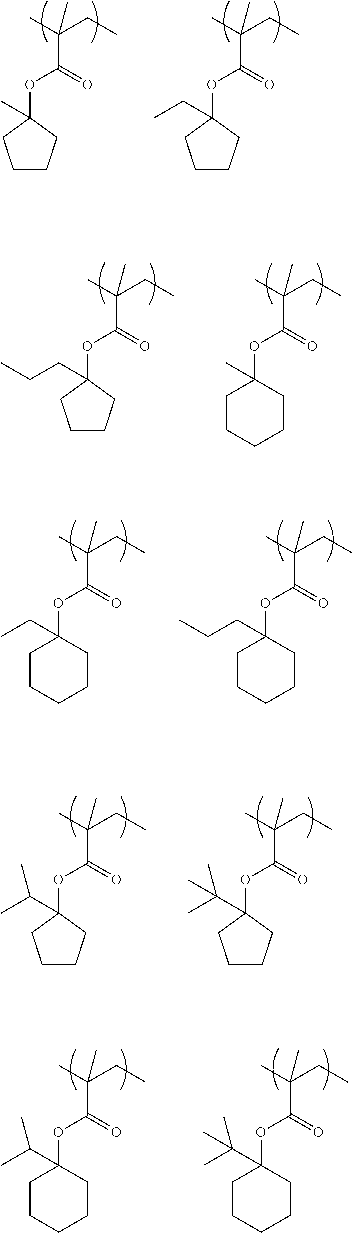

The resin of the Component (A) contained in the positive resist composition of the present invention preferably further contains a repeating unit having hydroxyl group and/or a lactone ring in addition to the repeating unit represented by the general formula (1) and the repeating unit represented by the general formula (2). When the resin of the Component (A) contains such a repeating unit having a hydroxyl group or a lactone ring, adhesiveness is improved and sufficient rectangularity can be obtained even in a fine pattern.

The repeating unit having a hydroxyl group as an adhesive group may be exemplified by the following, but the repeating unit is not limited by these.

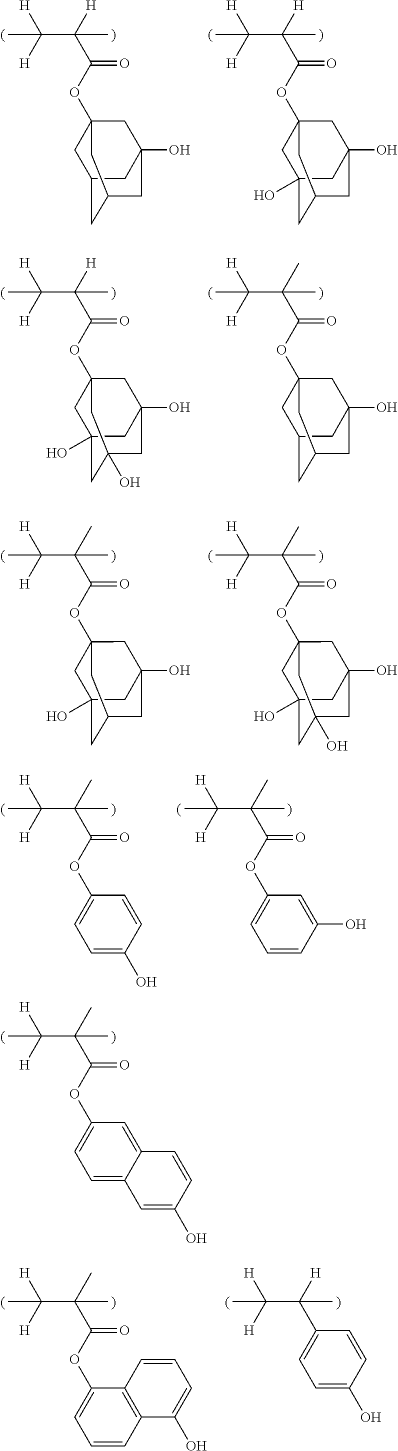

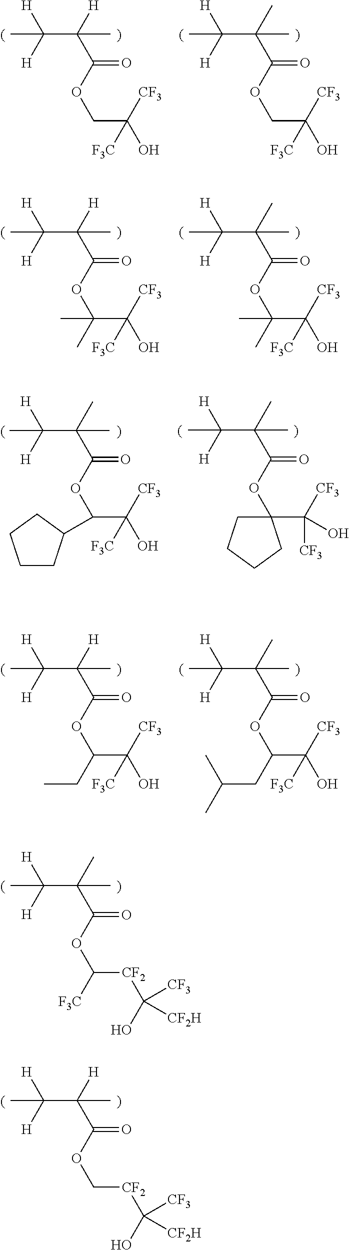

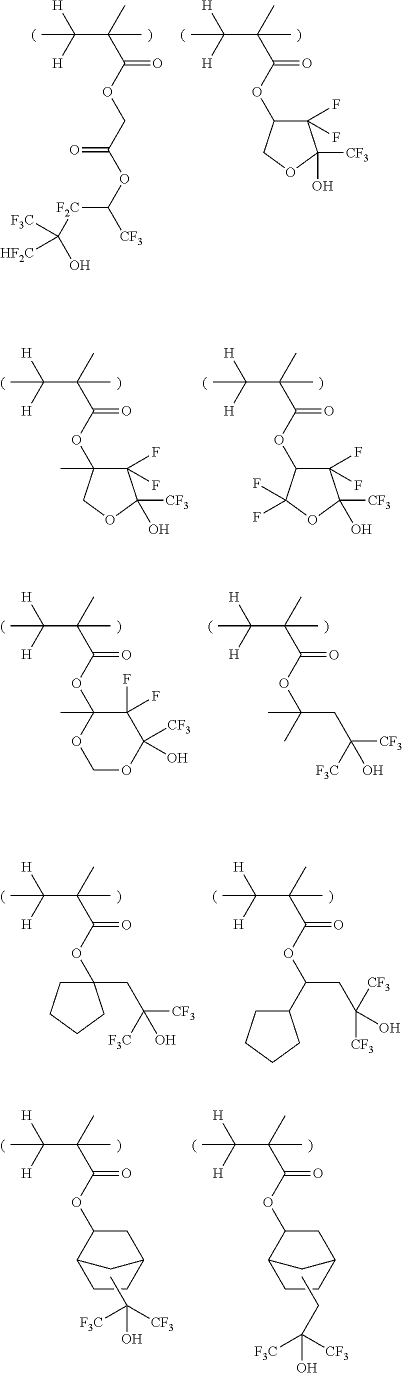

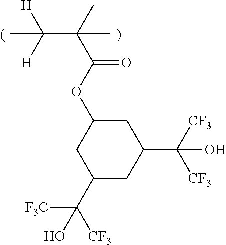

The repeating unit having a lactone ring as an adhesive group may be exemplified by the following, but the repeating unit is not limited by these.

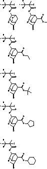

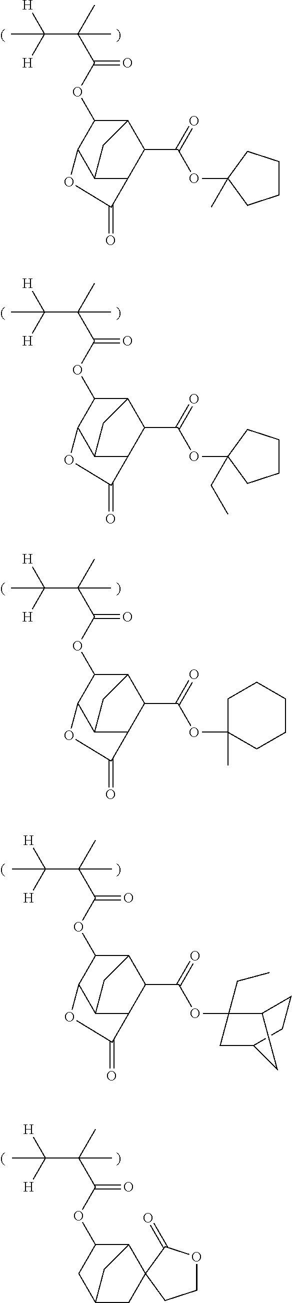

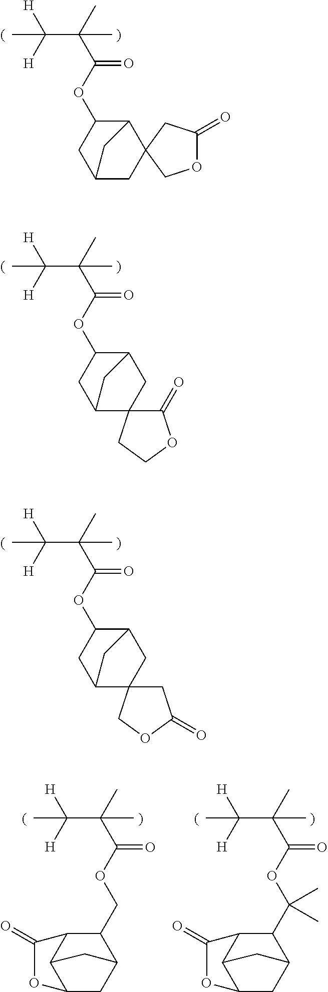

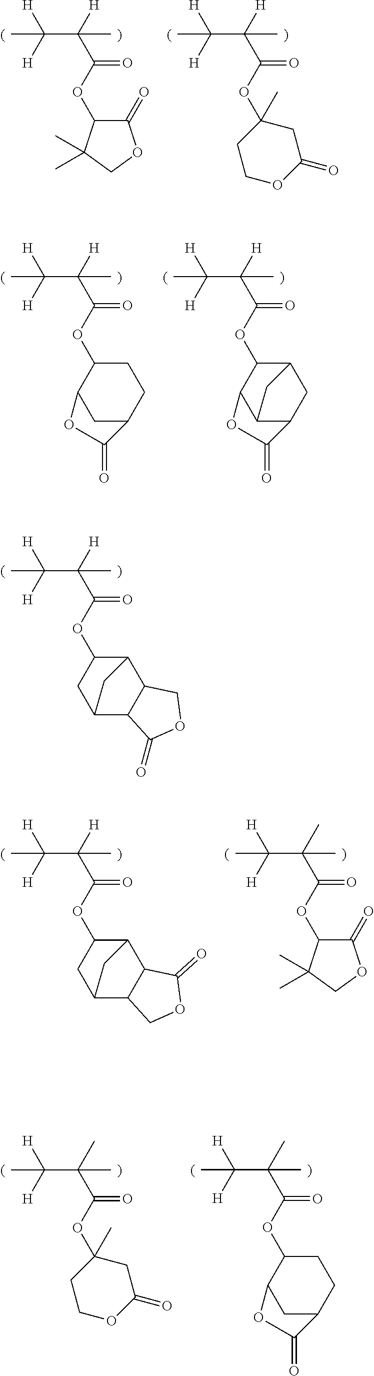

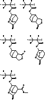

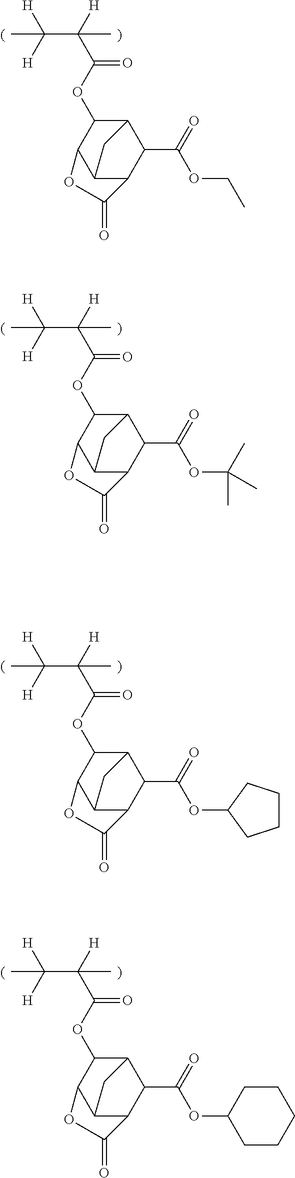

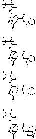

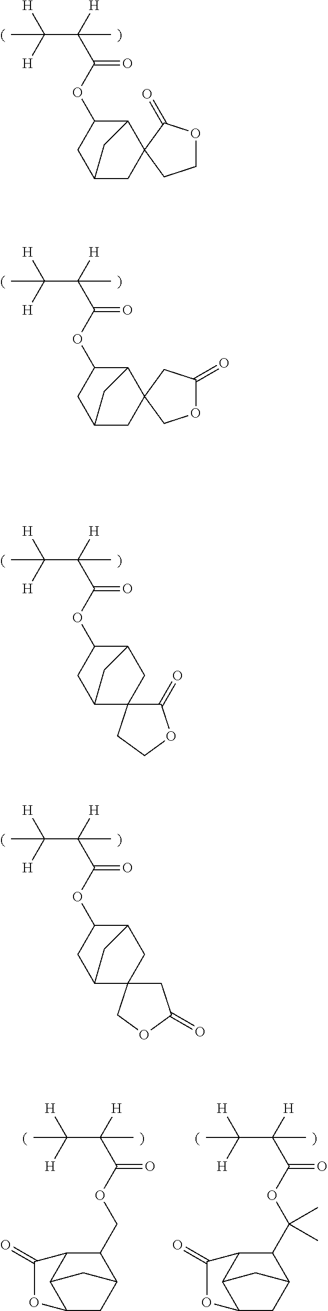

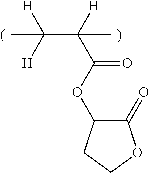

Among these, it is particularly preferred to contain a repeating unit(s) either of the following structural formula (4) or the following structural formula (5), or both of them.

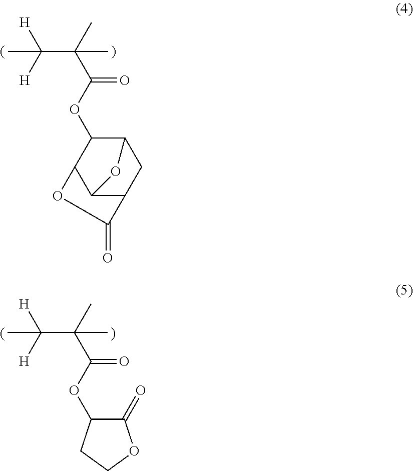

The resin of the Component (A) in the positive resist composition of the present invention may contain other repeating unit(s) than the repeating units having the structures represented by the general formulae (1) and (2), and a hydroxyl group and/or a lactone ring-containing unit(s), if necessary, and such a repeating unit(s) may be exemplified by a unit containing a carboxyl group or a fluoroalkyl group.

At this time, a content of the repeating unit containing the carboxyl group is preferably 10 mole % or less relative to the sum of the whole repeating units. If the content is in the range, there is no fear that rectangularity of the pattern is impaired, or pattern collapse resistance is deteriorated by swelling, and there is a case where it is effective in the point of controlling the dissolution rate.

Also, a content of the unit containing a fluoroalkyl group is preferably 20 mole % or less relative to the sum of the whole repeating units.

The resin may further contain a unit having a bridged cyclic structure.

A content of the unit is preferably less than 10 mole % relative to the sum of the whole repeating units since it can be admitted that pattern collapse can be prevented from occurring at the time of development more certainly, and there is no fear of deteriorating LWR.

Specific examples of these units containing a carboxyl group or a fluoroalkyl group, and units having a bridged cyclic structure are shown below, but these units are not limited by them.

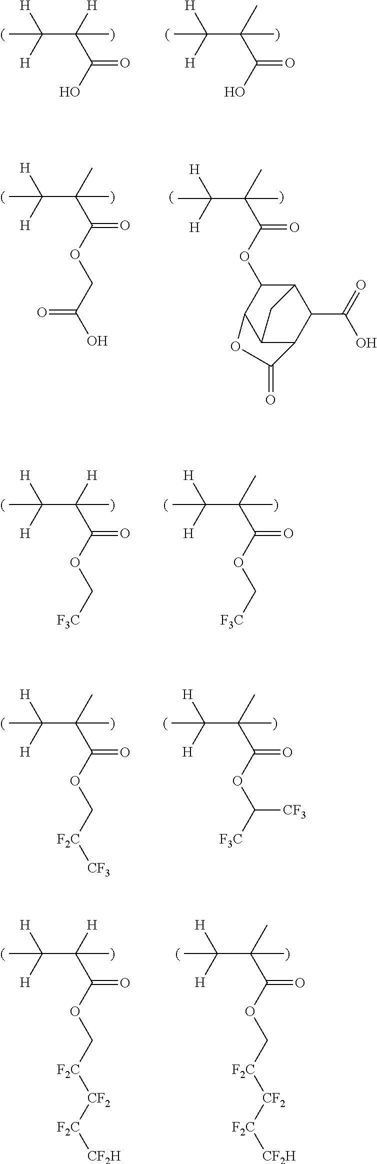

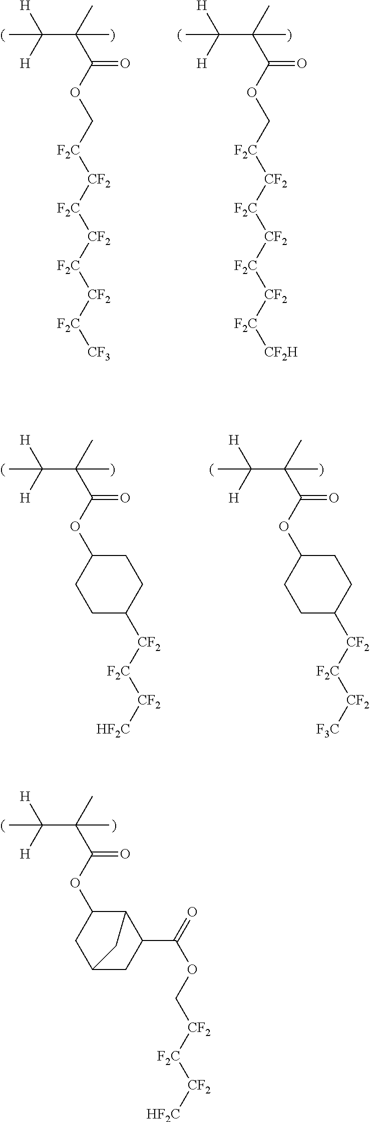

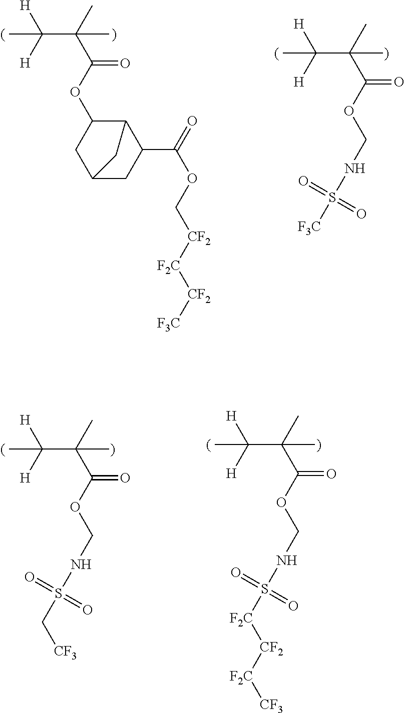 [SMILES: CCC(C)(C)C(=O)OC1CC2CC(C(=O)OCC(F)(F)C(F)(F)C(F)(F)C(F)(F)F)C1C2 ; CCC(C)(C)C(=O)OCNS(=O)(=O)C(F)(F)F ; CCC(C)(C)C(=O)OCNS(=O)(=O)CC(F)(F)F ; CCC(C)(C)C(=O)OCNS(=O)(=O)C(F)(F)C(F)(F)C(F)(F)C(F)(F)F]

When the resin of the Component (A) is synthesized, polymerizable monomers corresponding to the repeating units represented by the general formulae (1) and (2) which are essential repeating units, and polymerizable monomers corresponding to the repeating units represented by the structural formulae (4) and (5) which are optional repeating units are mixed, and polymerization is carried out by adding an initiator and/or a chain transfer agent.

With regard to the compositional ratio of the respective repeating units constituting the resin of the Component (A) in the positive resist composition of the present invention, when a content of the sum of the repeating units represented by the general formula (1) is made “a” mole %, a content of the sum of the repeating units represented by the general formula (2) is made “b” mole %, and a content of the sum of the repeating units having a hydroxyl group or a lactone ring is made “c” mole %, the compositional ratio preferably satisfy the following,

a+b+c=100

0<a≦50

10≦b≦60

20≦c≦70

and particularly preferably satisfy the following.

a+b+c=100

0<a≦40

10≦b≦60

30≦c≦60

The molecular weight of the resin of the Component (A) is preferably 1,000 to 500,000, more preferably 8,000 to 10,000 in a weight average molecular weight (Mw) measured by gel permeation chromatography (GPC) in terms of polystyrene. If the resin has such a molecular weight, generation of dissolution in water due to too small molecular weight, and lowering of solubility in an alkali or causing of coating defects at the time of spin coating due to too large molecular weight, can be suppressed.

### <Component (B)>

The positive resist composition of the present invention contains a photoacid generator as Component (B). The photoacid generator is not particularly limited, and those described in, for example, Japanese Patent Laid-Open Publication No. 2011-095662 may be used.

Incidentally, the photoacid generator to be preferably used in the positive resist composition of the present invention may be exemplified by a sulfonium salt, bissulfonyldiazomethane, N-sulfonyloxyimide, etc. The photoacid generator may be used a kind alone or two or more kinds in admixture.

A content of the Component (B) is preferably 0.5 to 25 parts by mass relative to 100 parts by mass of the resin of the Component (A).

### <Component (C)>

The positive resist composition of the present invention contains a compound represented by the following general formula (3) as Component (C). This Component (C) is a basic compound which becomes a quencher to the acid generated from the photoacid generator of the Component (B),

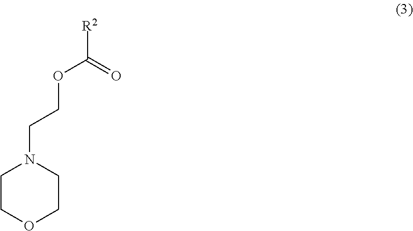

wherein R² represents a linear or branched alkyl group having 10 to 20 carbon atoms which may contain an ether bond(s) and an ester bond(s).

The Component (C) is preferably a compound where, in particular, R² is a linear alkyl group having 10 to 20 carbon atoms, further preferably compounds having the following structures.

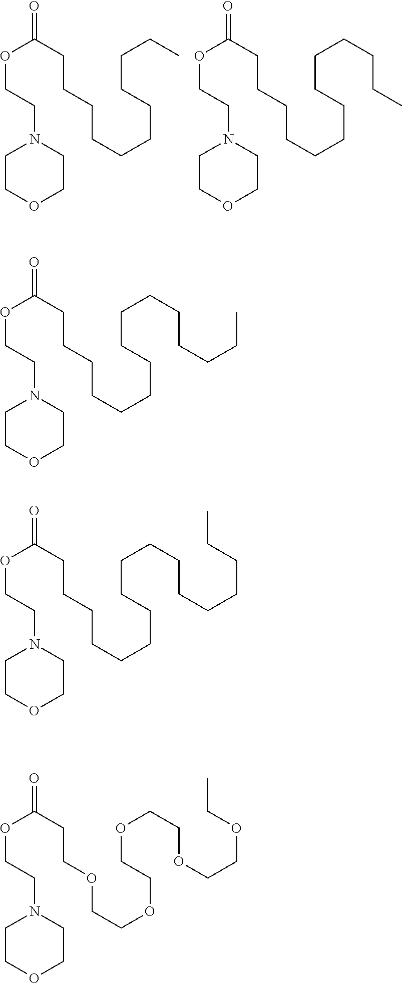

A content of the Component (C) is preferably 0.5 to 10 parts by mass relative to 100 parts by mass of the resin of the Component (A). If the content of the Component (C) is in such a range, the effects of the present invention can be shown sufficiently.

### <Component (D)>

The positive resist composition of the present invention contains a solvent as Component (D).

The Component (D) may be any organic solvents as long as it can dissolve the resin of the Component (A), the photoacid generator of the Component (B), the compound of the Component (C), and other additives, etc. By adding the organic solvent, for example, coating property of the resist composition to the substrate, etc., can be improved.

Examples of such an organic solvent include ketones such as cyclohexanone, methyl-2-n-amyl ketone; alcohols such as 3-methoxybutanol, 3-methyl-3-methoxybutanol, 1-methoxy-2-propanol, 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol mono-tert-butyl ether acetate; lactones such as γ-butyrolactone; and these may be used one kind alone or two or more kinds in admixture, but the solvent is not limited by these.

In the present invention, among these organic solvents, diethylene glycol dimethyl ether which is the most excellent in solubility of an acid generator in the resist components, or 1-ethoxy-2-propanol, propylene glycol monomethyl ether acetate, cyclohexanone, and a mixed solvent thereof are preferably used.

An amount of the solvent of the Component (D) to be used is preferably 200 to 5,000 parts by mass, in particular, 400 to 4,000 parts by mass relative to 100 parts by mass of the resin of the Component (A).

### <Other Components>

Also, to the positive resist composition of the present invention, a compound generating an acid by decomposing with an acid (acid amplifier compound) may be added. As the acid amplifier compound, those disclosed in, for example, Japanese Patent Laid-Open Publication No. 2009-269953 may be used.

An amount of the acid amplifier compound to be added to the resist composition of the present invention is 2 parts by mass or less, preferably 1 part by mass or less relative to 100 parts by mass of the resin of the Component (A). If it is 2 parts by mass or less, there is no fear that control of acid diffusion becomes difficult, and that deterioration of resolution or deterioration of the pattern shape is occurred.

Further, to the positive resist composition of the present invention, a compound (dissolution controlling agent) having a weight average molecular weight of 3,000 or less which changes solubility in an alkali developer by the action of an organic acid derivative or an acid may be added, and those disclosed in, for example, Japanese Patent Laid-Open Publication No. 2009-269953 may be used.

By adding the dissolution controlling agent, difference in dissolution rates between the exposed portion and the unexposed portion can be made larger, and resolution can be further improved.

Moreover, to the positive resist composition of the present invention, a basic compound other than the Component (C) may be added. By adding the basic compound, resolution can be further improved. As the basic compound, a primary, secondary or tertiary amine compound, in particular, an amine compound having a hydroxyl group, an ether group, an ester group, a lactone ring, a cyano group, or a sulfonic acid ester group disclosed at the paragraphs (0146) to (0164) of Japanese Patent Laid-Open Publication No. 2008-111103, or a compound having a carbamate group disclosed in Japanese Patent Laid-Open Publication No. 2001-166476 may be used. An amount of such a basic compound to be added is preferably 0 to 4 parts by mass relative to 100 parts by mass of the resin of the Component (A).

Furthermore, to the positive resist composition of the present invention, a surfactant component may be added. The surfactant component is not particularly limited and, for example, an alkali-soluble surfactant disclosed in Japanese Patent Laid-Open Publication No. 2008-111103 may be used. By adding the surfactant, coating property of the resist composition can be further improved or controlled.

Also, the surfactants may be used in admixture, and a total amount thereof to be added is 0.001 to 20 parts by mass, preferably 0.01 to 10 parts by mass relative to 100 parts by mass of the resin of the Component (A).

As mentioned above, according to the present invention, a positive resist composition excellent in resolution, in particular excellent in depth of focus (DOF) characteristics in both of the isolated pattern and the trench pattern, and which can form a resist pattern with good LWR can be provided.

The positive resist composition of the present invention gives excellent resolution and an excellent pattern shape as mentioned above by the usual lithography technology (including the multi-layer resist method, etc.) such as pattern exposure, development, etc., and, in particular, it is extremely useful in a liquid immersion lithography in which a top coat is formed on a photoresist film, and exposure is carried out through water.

Thus, the present invention provides a patterning process, comprising:

forming a photoresist film by coating the above-mentioned positive resist composition of the present invention on a substrate and subjecting to heat treatment;

forming a top coat on the photoresist film;
subjecting to liquid immersion exposure with a high energy beam having a wavelength of 180 to 250 nm through water; and developing using an alkali developer.

In the following, the patterning process of the present invention is described in detail.

For forming a pattern using the positive resist composition of the present invention, it may be carried out by using the conventionally known lithography technology.

For example, the positive resist composition of the present invention is coated on a substrate for manufacturing an integrated circuit (Si, SiO₂, SiN, SiON, TiN, WSi, BPSG, SOG, a substrate to which an organic anti-reflection film has been formed, etc.), or a substrate for manufacturing a mask circuit (Cr, CrO, CrON, MoSi, etc.) by spin-coating method, etc., with a film thickness of 0.05 to 2.0 μm, and subjected to heat treatment (prebaking) on a hot plate at 60 to 150° C. for 1 to 10 minutes, preferably at 80 to 140° C. for 1 to 5 minutes to form a photoresist film on the substrate.

Then, a top coat is formed on the obtained photoresist film.

The top coat is a material insoluble in water, is used for preventing elution of a material from the photoresist film, and for increasing water-sliding property of the film surface, and can be roughly classified into two kinds. One of which is an organic solvent peeling type in which peeling is necessary before alkali development by an organic solvent which does not dissolve the photoresist film, and the other is an alkali soluble type which is soluble in an alkali developer and the top coat is removed with the resist film soluble part.

The latter is, in particular, preferably a material comprising a polymer compound having a 1,1,1,3,3,3-hexafluoro-2-propanol residue which is insoluble in water and soluble in an alkali developer as a base, and dissolved in an alcohol-based solvent containing alcohol having 4 or more carbon atoms, an ether-based solvent containing ether having 8 to 12 carbon atoms, and a mixed solvent thereof.

A material in which the above-mentioned surfactant which is insoluble in water and soluble in an alkali developer is dissolved in an alcohol-based solvent containing alcohol having 4 or more carbon atoms, an ether-based solvent containing ether having 8 to 12 carbon atoms, or a mixed solvent thereof may be also used.

Also, as a means of the patterning process, after formation of the photoresist film, pure water rinsing (post-soaking) may be carried out for extracting an acid generator from the film surface or washing particles away from the film surface, and after exposure, rinsing (post-soaking) may be carried out for removing water droplets remained on the film.

Next, a mask for forming an objective pattern is held up over the photoresist film, and liquid immersion exposure is carried out by a high energy beam having a wavelength of 180 to 250 nm such as a far ultraviolet ray, an excimer laser, etc., through water between the mask and the substrate (Immersion method). Irradiation is preferably carried out so that the exposure dose is to be 1 to 200 mJ/cm², in particular, 10 to 100 mJ/cm². The positive resist composition of the present invention is the most suitable for fine patterning by such a far ultraviolet ray or an excimer laser having a wavelength of 180 to 250 nm.

Then, post-exposure bake (PEB) is carried out on a hot plate at 60 to 150° C. for 1 to 5 minutes, preferably at 80 to 140° C. for 1 to 3 minutes. Further, by using a developer of an aqueous alkaline solution such as 0.1 to 5% by mass, preferably 2 to 3% by mass of tetramethyl ammonium hydroxide (TMAH), etc., for 0.1 to 3 minutes, preferably for 0.5 to 2 minutes, according to the conventional method such as a dipping method, a puddle method, a spray method, etc., thereby the objective pattern is formed on the substrate.

When the patterning process of the present invention as mentioned above is employed, by using the positive resist composition of the present invention, deterioration of the pattern shape or resolution which is likely occurred when liquid immersion exposure is carried out by forming the conventional top coat can be suppressed. Specifically, a pattern shape having high rectangularity can be obtained, and excellent depth of focus (DOF) characteristics, specifically excellent DOF characteristics of a trench pattern and an isolated pattern can be obtained.

### EXAMPLES

In the following, the present invention is explained more specifically by referring to Examples and Comparative Examples, but the present invention is not limited by these descriptions.

A compositional ratio (molar ratio) and a molecular weight (Mw) of the repeating units constituting the resin to be used in the evaluation are shown in Table 1. Incidentally, the molecular weight (Mw) represents a weight average molecular weight measured by GPC in terms of polystyrene. The structures of the respective repeating units are shown in Table 2.

Incidentally, among the resins in Table 1, P1 to P7 correspond to the resins of the Component (A) which are essential components of the positive resist composition of the present invention.

TABLE 1

| | Unit 1 | | Unit 2 | | Unit 3 | | Unit 4 | | |
|---|---|---|---|---|---|---|---|---|---|
| | (Intro- | | (Intro- | | (Intro- | | (Intro- | | |
| | duced | | duced | | duced | | duced | | |
| Resin | ratio) | | ratio) | | ratio) | | ratio) | | Mw |
| P1 | A-1 | (0.35) | A-3 | (0.10) | L-1 | (0.10) | L-2 | (0.45) | 9,100 |
| P2 | A-1 | (0.35) | A-4 | (0.15) | L-2 | (0.40) | L-4 | (0.10) | 8,700 |
| P3 | A-1 | (0.30) | A-5 | (0.15) | L-1 | (0.10) | L-2 | (0.45) | 9,500 |
| P4 | A-2 | (0.30) | A-3 | (0.15) | L-1 | (0.15) | L-2 | (0.40) | 9,100 |
| P5 | A-2 | (0.25) | A-5 | (0.15) | L-1 | (0.10) | L-2 | (0.50) | 8,800 |
| P6 | A-2 | (0.25) | A-6 | (0.15) | L-2 | (0.45) | L-4 | (0.15) | 9,000 |
| P7 | A-1 | (0.30) | A-5 | (0.10) | L-2 | (0.50) | L-4 | (0.10) | 9,000 |
| P8 | A-1 | (0.40) | L-2 | (0.60) | | | | | 7,000 |
| P9 | A-1 | (0.40) | L-2 | (0.50) | H-1 | (0.10) | | | 7,800 |
| P10 | A-2 | (0.10) | L-2 | (0.60) | | | | | 6,900 |
| P11 | A-3 | (0.50) | L-1 | (0.50) | | | | | 7,500 |
| P12 | A-4 | (0.50) | L-4 | (0.50) | | | | | 8,000 |
| P13 | A-5 | (0.40) | L-3 | (0.60) | | | | | 8,800 |
| P14 | A-6 | (0.40) | L-1 | (0.50) | H-1 | (0.10) | | | 7,800 |
| P15 | A-7 | (0.40) | L-1 | (0.50) | H-1 | (0.10) | | | 7,600 |
| P16 | A-6 | (0.20) | A-7 | (0.30) | L-5 | (0.50) | | | 7,100 |
| P17 | A-4 | (0.15) | A-7 | (0.30) | L-2 | (0.45) | L-4 | (0.10) | 7,900 |
| P10 | A-4 | (0.25) | A-8 | (0.20) | L-2 | (0.45) | H-1 | (0.10) | 7,800 |
| P19 | A-5 | (0.25) | A-8 | (0.20) | L-1 | (0.45) | H-1 | (0.10) | 8,100 |

TABLE 2

| | |
|---|---|
| 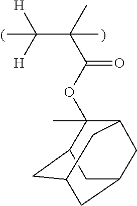 | A-1 |
| 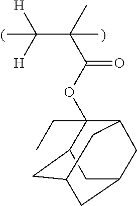 | A-2 |
| 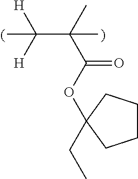 | A-3 |
| 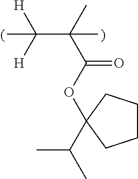 | A-4 |
| 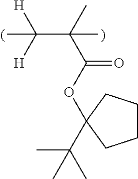 | A-5 |
| 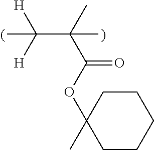 | A-6 |
| 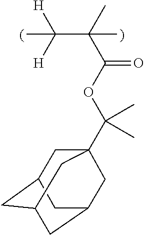 | A-7 |
| 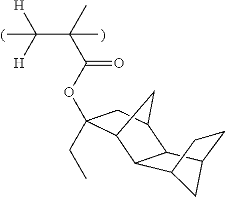 | A-8 |
| 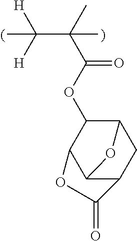 | L-1 |
| 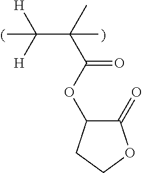 | L-2 |
| 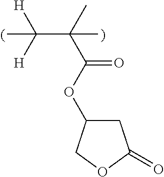 | L-3 |
| 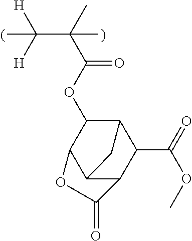 | L-4 |
| 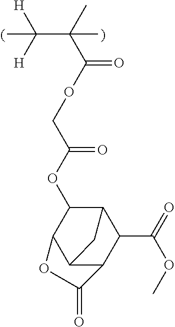 | L-5 |
| 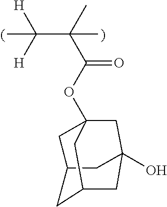 | H-1 |

### (Preparation of Resist Composition)

Next, in addition to the resins, various kinds of the photoacid generators and various kinds of the quenchers (basic compounds) were dissolved in solvents with the formulation ratio (parts by mass) shown in the following Table 3 and Table 4, and after dissolution, the solution was filtered by using a filter (pore diameter: 0.2 μm) made of Teflon (Registered Trademark) to a prepare resist composition. Incidentally, the solvents shown in Table 3 and Table 4 are as mentioned below.

PGMEA: Propylene glycol monomethyl ether acetate

CyHO: Cyclohexanone

TABLE 3

| Resist | Resin | | | Solvent 1 | Solvent 2 |
|---|---|---|---|---|---|
| com- | (80 parts | Photoacid | Basic | (1,428 parts | (612 parts by |
| position | by mass) | generator | compound | by mass) | mass) |
| R1 | P1 | PAG-1 (10) | Q-3 (3.5) | PGMEA | CyHO |
| | | PAG-2 (5) | | | |
| R2 | P2 | PAG-1 (10) | Q-2 (3.5) | PGMEA | CyHO |
| | | PAG-2 (5) | | | |
| R3 | P3 | PAG-1 (10) | Q-4 (3.5) | PGMEA | CyHO |
| | | PAG-2 (5) | | | |
| R4 | P4 | PAG-1 (10) | Q-3 (3.5) | PGMEA | CyHO |
| | | PAG-2 (5) | | | |
| R5 | 25 | PAG-1 (10) | Q-1 (3.5) | PGMEA | CyHO |
| | | PAG-2 (5) | | | |
| R6 | P6 | PAG-1 (10) | Q-4 (3.5) | PGMEA | CyHO |
| | | PAG-2 (5) | | | |
| R7 | P7 | PAG-1 (10) | Q-2 (3.5) | PGMEA | CyHO |
| | | PAG-2 (5) | | | |
| R8 | P8 | PAG-1 (10) | Q-2 (3.5) | PGMEA | CyHO |
| | | PAG-2 (5) | | | |
| R9 | P9 | PAG-1(10) | Q-4 (3.5) | PGMEA | CyHO |
| | | PAG-2 (5) | | | |
| R10 | P10 | PAG-1 (10) | Q-1 (3.5) | PGMEA | CyHO |
| | | PAG-2 (5) | | | |
| R11 | P11 | PAG-1 (10) | Q-3 (3.5) | PGMEA | CyHO |
| | | PAG-2 (5) | | | |
| R12 | P12 | PAG-1 (10) | Q-2 (3.5) | PGMEA | CyHO |
| | | PAG-2 (5) | | | |
| R13 | P13 | PAG-1 (10) | Q-3 (3.5) | PGMEA | CyHO |
| | | PAG-2 (5) | | | |
| R14 | P14 | PAG-1 (10) | Q-4 (3.5) | PGMEA | CyHO |
| | | PAG-2 (5) | | | |
| R15 | P15 | PAG-1 (10) | Q-2 (3.5) | PGMEA | CyHO |
| | | PAG-2 (5) | | | |
| R16 | P16 | PAG-1 (10) | Q-3 (3.5) | PGMEA | CyHO |
| | | PAG-2 (5) | | | |
| R17 | P17 | PAG-1 (10) | Q-2 (3.5) | PGMEA | CyHO |
| | | PAG-2 (5) | | | |
| R18 | P18 | PAG-1 (10) | Q-4 (3.5) | PGMEA | CyHO |
| | | PAG-2 (5) | | | |
| R19 | P19 | PAG-1 (10) | Q-4 (3.5) | PGMEA | CyHO |
| | | PAG-2 (5) | | | |

TABLE 4

| Resist | Resin | | | Solvent 1 | Solvent 2 |
|---|---|---|---|---|---|
| com- | (80 parts | Photoacid | Basic | (1,428 parts | (612 parts by |
| position | by mass) | generator | compound | by mass) | mass) |
| R20 | P2 | PAG-1 (10) | Q-6 (3.5) | PGMEA | CyHO |
| | | PAG-2 (5) | | | |
| R21 | P2 | PAG-1 (10) | Q-7 (3.5) | PGMEA | CyHO |
| | | PAG-2 (5) | | | |
| R22 | P2 | PAG-1 (10) | Q-8 (3.5) | PGMEA | CyHO |
| | | PAG-2 (5) | | | |
| R23 | 22 | PAG-1 (10) | Q-9 (3.5) | PGMEA | CyHO |
| | | PAG-2 (5) | | | |
| R24 | P6 | PAG-1 (10) | Q-7 (3.5) | PGMEA | CyHO |
| | | PAG-2 (5) | | | |
| R25 | P6 | PAG-1 (10) | Q-8 (3.5) | PGMEA | CyHO |
| | | PAG-2 (5) | | | |
| R26 | P6 | PAG-1 (10) | Q-9 (3.5) | PGMEA | CyHO |
| | | PAG-2 (5) | | | |
| R27 | P6 | PAG-1 (10) | Q-6 (3.5) | PGMEA | CyHO |
| | | PAG-2 (5) | | | |
| R28 | P3 | PAG-1 (15) | Q-7 (3.5) | PGMEA | CyHO |
| R29 | P6 | PAG-1 (15) | Q-8 (3.5) | PGMEA | CyHO |
| R30 | P7 | PAG-1 (5) | Q-9 (3.5) | PGMEA | CyHO |
| | | PAG-2 (10) | | | |
| R31 | P2 | PAG-1 (15) | Q-1 (3.5) | PGMEA | CyHO |
| R32 | P2 | PAG-1 (15) | Q-2 (3.5) | PGMEA | CyHO |
| R33 | P2 | PAG-1 (10) | Q-3 (3.5) | PGMEA | CyHO |
| | | PAG-2 (10) | | | |
| R34 | P3 | PAG-1 (15) | Q-1 (3.5) | PGMEA | CyHO |
| R35 | P3 | PAG-1 (5) | Q-2 (3.5) | PGMEA | CyHO |
| | | PAG-2 (10) | | | |
| R36 | P3 | PAG-1 (15) | Q-3 (3.5) | PGMEA | CyHO |

Also, the structures of the photoacid generators (PAG-1, PAG-2) and the basic compounds (Q1 to Q9) in Table 3 and Table 4 are shown in Table 5. Incidentally, among the basic compounds in Table 5, Q1 to Q5 correspond to the compound of the Component (C) which is an essential component of the positive resist composition of the present invention.

That is, among the resist compositions shown in Table 3 and Table 4, R1 to R7 and R31 to R36 correspond to the positive resist composition of the present invention. R8 to R30 are resist compositions for Comparative Examples.

TABLE 5

| | |
|---|---|
| 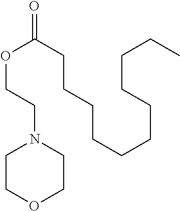 [SMILES: CCCCCCCCCCCC(=O)OCCN1CCOCC1] | Q-1 |
| 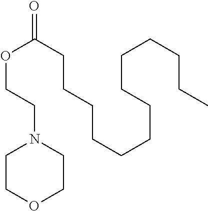 [SMILES: CCCCCCCCCCCCCC(=O)OCCN1CCOCC1] | Q-2 |
| 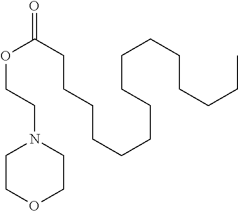 [SMILES: CCCCCCCCCCCCCCCC(=O)OCCN1CCOCC1] | Q-3 |
| 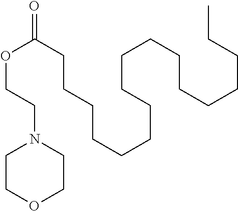 [SMILES: CCCCCCCCCCCCCCCCCC(=O)OCCN1CCOCC1] | Q-4 |
| 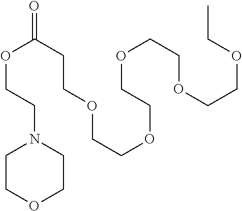 [SMILES: CCOCCOCCOCCOCCOCCC(=O)OCCN1CCOCC1] | Q-5 |
| 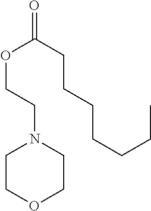 [SMILES: CCCCCCCC(=O)OCCN1CCOCC1] | Q-6 |
| 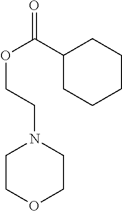 [SMILES: O=C(OCCN1CCOCC1)C1CCCCC1] | Q-7 |
| 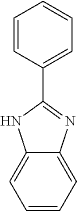 [SMILES: c1ccc(-c2nc3ccccc3[nH]2)cc1] | Q-8 |
| 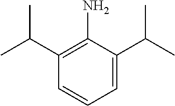 | Q-9 |
| 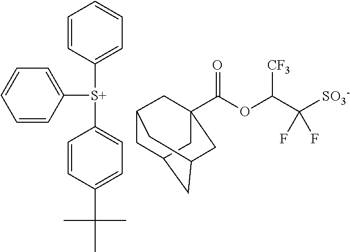 | PAG-1 |
| 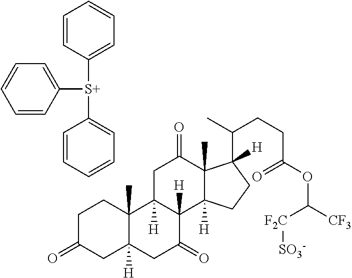 | PAG-2 |

### (Preparation of Resist Top Coat)

The base resins (TC Polymer 1 and TC Polymer 2) and organic solvents were mixed with the composition shown below, and after dissolution, the solution was filtered by using a filter (pore diameter: 0.2 μm) made of Teflon (Registered Trademark) to prepare top coat materials (TC-1 and TC-2). Incidentally, the solvents used are as mentioned below.

Organic solvent 1: Isoamyl ether

Organic solvent 2: 2-methyl-1-butanol

### TC-1

Mixed composition: TC Polymer 1 represented by the following formula (100 parts by mass), organic solvent 1 (2,600 parts by mass), organic solvent 2 (260 parts by mass)

### TC Polymer 1 (Molecular Weight: 7,500)

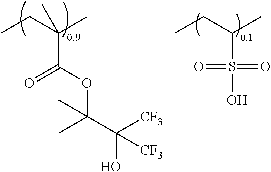

### TC-2

Mixed composition: TC Polymer 2 represented by the following formula (100 parts by mass), organic solvent 1 (2,600 parts by mass), organic solvent 2 (260 parts by mass)

### TC Polymer 2 (Molecular Weight: 8,200)

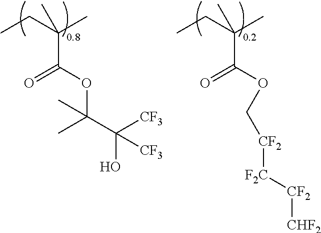

### Evaluation Method

### Examples 1 to 13 and Comparative Examples 1 to 23

On a silicon substrate was coated a solution of an anti-reflection film (ARC-29A available from Nissan Chemical Industries, Ltd.), and baked at 200° C. for 60 seconds. Each of the resist solutions (R1 to R36) was spin coated on the prepared substrate having an anti-reflection film (film thickness: 100 nm), and baked by using a hot plate at 100° C. for 60 seconds to form a photoresist film with a film thickness of 100 nm.

Onto the film was further coated the resist top coat material (TC-1 or TC-2), and baked at 100° C. for 60 seconds to form a top coat with a thickness of 50 nm. The resulting material was subjected to liquid immersion exposure using an ArF excimer laser scanner (NSR-S610C manufactured by Nikon Corporation, NA=1.30, σ 0.85, ¾ zonal illumination, 6% halftone phase shift mask) through water, baked (PEB) at an optional temperature (shown in Tables 6 and 7) for 60 seconds, and subjected to development by an aqueous solution containing 2.38% by mass of tetramethyl ammonium hydroxide for 60 seconds to form a pattern.

Evaluation of the resist was carried out the 50 nm line/100 nm pitch pattern as a subject, and an exposure dose which gave a line width of 45 nm by an electron microscope was made an optimum exposure dose (Eop, mJ/cm²). A pattern roughness at that time was made LWR and compared.

Also, the focus was shifted up and down at the optimum exposure dose, and the range of the focus in which the pattern had been resolved with the dimensions of the target size of 45 nm±10% (i.e., 41 nm to 50 nm) was obtained, which was made DOF1 (nm). As this value is large, it can be said to be good performance where the margin for deviation of the focus is wide.

In addition, the pattern of 65 nm trench/160 nm pitch was simultaneously observed, and at the exposure dose which gave a 45 nm trench/160 nm pitch, the range of the focus in which the pattern had been resolved with the dimensions of the target size of 45 nm±10% (i.e., 41 nm to 50 nm) was obtained in the same manner, which was made DOF2 (nm). Evaluation results (Examples 1 to 13) of the resist compositions of the present invention (R1 to R7 and R31 to R36) shown in the Table 3 and Table 4 are shown in Table 6. In addition, evaluation results (Comparative Examples 1 to 23) of the resist compositions for Comparative Examples (R8 to R30) shown in the Table 3 and Table 4 are shown in Table 7.

TABLE 6

| | | | PEB | | | |
|---|---|---|---|---|---|---|
| | Resist | Top | temperature | DOF1 | DOF2 | LWR |
| Example | composition | coat | ( C.) | (nm) | (nm) | (nm) |
| 1 | R1 | TC-1 | 100 | 110 | 120 | 3.9 |
| 2 | R2 | TC-1 | 95 | 120 | 130 | 3.8 |
| 3 | R3 | TC-1 | 95 | 140 | 140 | 3.7 |
| 4 | R4 | TC-1 | 100 | 140 | 110 | 4.0 |
| 5 | R5 | TC-2 | 95 | 150 | 100 | 3.9 |
| 6 | R6 | TC-2 | 100 | 130 | 110 | 4.0 |
| 7 | R7 | TC-1 | 95 | 135 | 115 | 3.8 |
| 8 | R31 | TC-1 | 95 | 110 | 140 | 3.7 |
| 9 | R32 | TC-1 | 95 | 105 | 140 | 3.9 |
| 10 | R33 | TC-1 | 100 | 105 | 135 | 4.0 |
| 11 | R34 | TC-2 | 95 | 130 | 135 | 3.9 |
| 12 | R35 | TC-1 | 100 | 130 | 130 | 3.9 |
| 13 | R36 | TC-1 | 95 | 135 | 140 | 3.8 |

TABLE 7

| | | | PEB | | | |
|---|---|---|---|---|---|---|
| Comparative | Resist | Top | temperature | DOF1 | DOF2 | LWR |
| Example | composition | coat | (° C.) | (nm) | (nm) | (nm) |
| 1 | R8 | TC-1 | 90 | 90 | 80 | 4.6 |
| 2 | R9 | TC-1 | 95 | 100 | 85 | 4.7 |
| 3 | R10 | TC-1 | 90 | 105 | 75 | 4.9 |
| 4 | R11 | TC-1 | 90 | 65 | 100 | 4.3 |
| 5 | R12 | TC-1 | 85 | 90 | 90 | 4.1 |
| 6 | R13 | TC-1 | 80 | 105 | 100 | 4.1 |
| 7 | R14 | TC-1 | 90 | 90 | 100 | 4.8 |
| 8 | R15 | TC-1 | 85 | 90 | 95 | 4.9 |
| 9 | R16 | TC-1 | 85 | 100 | 90 | 4.7 |
| 10 | R17 | TC-1 | 90 | 110 | 100 | 4.4 |
| 11 | R18 | TC-1 | 80 | 120 | 70 | 4.9 |
| 12 | R19 | TC-1 | 75 | 115 | 90 | 4.6 |
| 13 | R20 | TC-1 | 95 | 115 | 120 | 4.3 |
| 14 | R21 | TC-1 | 95 | 110 | 125 | 4.1 |
| 15 | R22 | TC-1 | 95 | 100 | 90 | 4.4 |
| 16 | R23 | TC-2 | 95 | 80 | 90 | 4.6 |
| 17 | R24 | TC-1 | 95 | 115 | 125 | 4.2 |
| 18 | R25 | TC-2 | 95 | 100 | 75 | 4.3 |
| 19 | R26 | TC-2 | 95 | 90 | 90 | 4.5 |
| 20 | R27 | TC-1 | 95 | 110 | 120 | 4.2 |
| 21 | R28 | TC-2 | 90 | 125 | 115 | 4.1 |
| 22 | R29 | TC-1 | 95 | 110 | 110 | 4.5 |
| 23 | R30 | TC-1 | 100 | 120 | 125 | 4.1 |

As shown in Table 6, in Examples 1 to 13 using the positive resist compositions of the present invention (R1 to R7 and R31 to R36), DOF1 and DOF2 were 100 to 150, and LWR was 3.7 to 4.0; that is they were excellent in depth of focus (DOF) characteristics, and also excellent in LWR.

On the other hand, as shown in Table 7, in Comparative Examples 1 to 23 using the positive resist compositions in which Component (A) or Component (C) had not been contained (R8 to R30), DOF1 and DOF2 were 65 to 125, and LWR was 4.1 to 4.9; that is they were inferior in depth of focus (DOF) characteristics and LWR as compared with those of Examples.

From the above results, it can be clarified that if the positive resist composition of the present invention is used, a pattern excellent in resolution, in particular, excellent in depth of focus (DOF) characteristics and having good LWR can be formed.

It must be stated here that the present invention is not restricted to the embodiments shown above. The embodiments shown above are merely examples so that any embodiments composed of substantially the same technical concept as disclosed in the claims of the present invention and expressing a similar effect are included in the technical scope of the present invention.

What is claimed is:

1. A positive resist composition, comprising:
(A) a resin having repeating units represented by the following general formula (1) and the following general formula (2) as repeating units containing an acid-labile group, and an alkali solubility of which being increased by an acid;
(B) a photoacid generator;
(C) a compound represented by the following general formula (3); and
(D) a solvent, 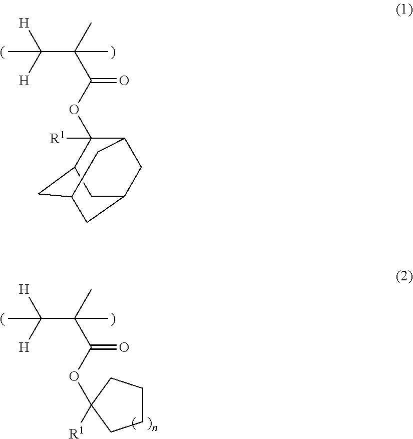
wherein each R¹ independently represents a linear or branched alkyl group having 1 to 10 carbon atoms; and “n” represents an integer of 1 to 3, 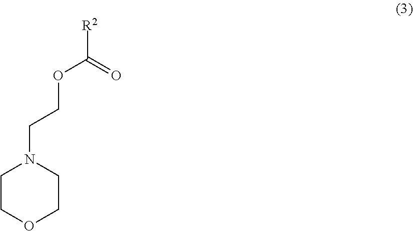
wherein R² represents a linear or branched alkyl group having 10 to 20 carbon atoms which may contain an ether bond(s) and an ester bond(s).

2. The positive resist composition according to claim 1, wherein the resin of the Component (A) further contains either or both of a repeating unit(s) represented by the following structural formula (4) and the following structural formula (5).

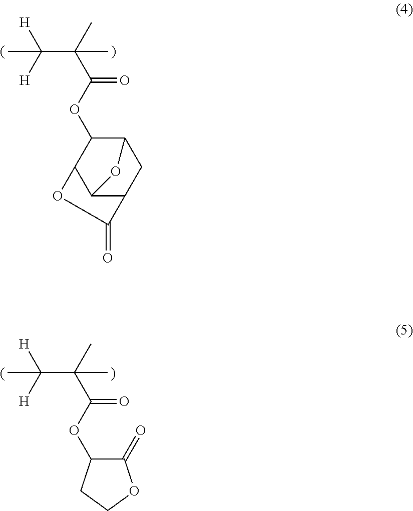

3. The positive resist composition according to claim 1, wherein a content of the Component (C) is 0.5 to 10 parts by mass relative to 100 parts by mass of the resin of the Component (A).

4. The positive resist composition according to claim 2, wherein a content of the Component (C) is 0.5 to 10 parts by mass relative to 100 parts by mass of the resin of the Component (A).

5. A patterning process, comprising:
forming a photoresist film by coating the positive resist composition according to claim 1 on a substrate and subjecting to heat treatment;
forming a top coat on the photoresist film;
subjecting to liquid immersion exposure with a high energy beam having a wavelength of 180 to 250 nm through water; and
developing using an alkali developer.

6. A patterning process, comprising:
forming a photoresist film by coating the positive resist composition according to claim 2 on a substrate and subjecting to heat treatment;
forming a top coat on the photoresist film;
subjecting to liquid immersion exposure with a high energy beam having a wavelength of 180 to 250 nm through water; and
developing using an alkali developer.

7. A patterning process, comprising:
forming a photoresist film by coating the positive resist composition according to claim 3 on a substrate and subjecting to heat treatment;
forming a top coat on the photoresist film;
subjecting to liquid immersion exposure with a high energy beam having a wavelength of 180 to 250 nm through water; and
developing using an alkali developer.

8. A patterning process, comprising:
forming a photoresist film by coating the positive resist composition according to claim 4 on a substrate and subjecting to heat treatment;
forming a top coat on the photoresist film;
subjecting to liquid immersion exposure with a high energy beam having a wavelength of 180 to 250 nm through water; and
developing using an alkali developer.
